(19) United States
(12) Patent Application Publication
(10) Pub. No.: US 2026/0231786 A1
(43) Pub. Date: Aug. 6, 2026

(54) ENCAPSULATED SEMICONDUCTOR PACKAGE AND A METHOD OF MANUFACTURING SUCH ENCAPSULATED SEMICONDUCTOR PACKAGE

(71) Applicant: NEXPERIA B.V., Nijmegen (NL)

(72) Inventor: Ricardo Lagmay Yandoc, Manchester (GB)

(73) Assignee: NEXPERIA B.V., Nijmegen (NL)

(21) Appl. No.: 19/530,479

(22) Filed: Feb. 5, 2026

(30) Foreign Application Priority Data
Feb. 5, 2025 (NL) 2039735

(51) Int. Cl. H10W 70/40; H10W 70/04; H10W 74/10

(52) U.S. Cl. CPC H10W 70/438; H10W 70/048; H10W 74/114; H10W 70/457

(57) ABSTRACT

The present disclosure proposes an encapsulated semiconductor package and a method of manufacturing such a encapsulated semiconductor package, the semiconductor package includes at least one lead terminal having an exposed lead end extending from the encapsulated semiconductor package, the exposed lead end includes a free lead end surface, the free lead end surface at least one notch, and the free lead end surface and the notch are plated with a plating material.

### CROSS-REFERENCE TO RELATED APPLICATIONS

This application claims the benefit under 35 U.S.C. § 119(a) of Dutch Patent Application No. NL 2039735 filed Feb. 5, 2025, the contents of which are incorporated by reference herein in their entirety.

### BACKGROUND

### 1. Field of the Disclosure

The present disclosure relates to an encapsulated semiconductor package with at least one exposed lead terminal structured for mounting on a printed circuit board and a to a method of manufacturing such encapsulated semiconductor package.

### 2. Description of the Related Art

Encapsulated semiconductor packages are essential for protecting semiconductor die structures against physical damage or dust contamination by means of encapsulation with a molding resin. Additionally, the package offers a way to connect the internal semiconductor die structures by means of exposed lead terminals to a substrate with electronic circuitry, known as a printed circuit board (PCB), such that the semiconductor die structure can fulfil its function in the overall circuit.

Typically, the semiconductor packages are connected at their lead terminals with solder to the PCB, creating a mechanically fixed and electrically conductive connection. In particular cases, to improve the connection a thin plating layer is provided on the semiconductor package's lead terminals.

Unfortunately, due to the current manufacturing processes, it cannot be guaranteed that the plating layer provided on the lead terminal suffices. Furthermore, to make that promise true with the current manufacturing processes, the size of the lead terminal would need to increase, thereby jeopardizing the overall size and the functioning of the semiconductor package.

It is thus the goal of the current disclosure to provide a new semiconductor package and a method of manufacturing one having an improved plating on its lead terminals.

### SUMMARY

In a first aspect, the disclosure pertains to an encapsulated semiconductor package comprising at least one lead terminal having an exposed lead end extending from the encapsulated semiconductor package, wherein the exposed lead end comprises a free lead end surface, wherein the free lead end surface comprises at least one notch, wherein the free lead end surface and the at least one notch are plated with a plating material.

Throughout the disclosure the free lead end surface can be understood as the surface of the lead terminal furthest away from the encapsulant, which thus does not share contour or ribs with the encapsulated semiconductor package. E.g. when the lead terminals would be a rectangular bar extending out of the encapsulant, one surface would be encapsulated, four would be partially encapsulated, thereby sharing an interface with the encapsulant, however, one surface would not be encapsulated and would not share an interface with the encapsulant. Exactly this surface would be the free lead end surface.

The inventors have found that an improved electrical and mechanical connection with a PBC can be efficiently obtained when at least the free lead end surface of the lead terminal is fully plated. To even further improve the mechanical connection with the PBC, the inventors have found that at least one fully plated notch provided in the free lead end surface needs to be present. It will be understood by the expert in the field that said notch will be filled with solder material upon (reflow) soldering of the semiconductor package to the PCB, creating an anchor with the PCB.

An encapsulated semiconductor package is to be understood to comprise a substrate, at least one semiconductor die mounted onto the substrate, at least one lead terminal, bonding means electrically connecting the at least one semiconductor die with the at least one lead terminal, as well as an encapsulant encapsulating the at least one semiconductor die, the bonding means, and partially encapsulating the at least one lead terminal, such that a free end of the at least one lead terminal can be used for further connecting the semiconductor package to further electronic circuitry.

A further benefit of the semiconductor package according to the disclosure is that the lead terminals can be made of standard dimensions, thereby not jeopardizing the overall size of the semiconductor package. In essence, the fully plated surface area at the front of the lead terminal is maximized by plating the free lead end surface and by providing at least one fully plated notch therein. This ensures that the effective front surface area is larger than 100% of the free lead end surface projection, while additionally all being plated. In the prior art, it is impossible to manufacture fully plated lead terminals, while at the same time comprising a fully plated notch, since the typical manufacturing processes do not lend themselves to that. The method of the disclosure will accordingly be discussed in a paragraph further below.

It should be clear to the expert in the field that the wording “fully plated” mean that during the processing step of plating said surface, it is intended to cover substantially all surface with plating material. Due to uncertainty in the manufacturing process, it may be such that the at least 95% of the surface is covered, preferably at least 98%.

In an example of the encapsulated semiconductor, the exposed lead end comprises a top lead surface and a bottom lead surface opposite to the top lead surface, both top surface and bottom surface extending from the encapsulated semiconductor package towards the free lead end surface. The exposed lead end further comprises a first side surface and a second side surface opposite to the first side surface, both extending from the encapsulated semiconductor package to the lead end surface, wherein the first side surface and the second side surface both extend from the top lead surface to the bottom lead surface, wherein the each of the first side surface and the second side surface comprise a first side surface portion and a second side surface portion, the first side portion being in proximity of the free lead end surface and the second side portion being in proximity of the encapsulated semiconductor package, wherein the first side surface portion is at least partially plated with plating material.

A benefit of having a first side surface portion being at least partially plated, while in the proximity of the free lead end surface is that solder upon (reflow) soldering is being attracted due to surface adhesion forces to the plated surfaces of the lead terminal. Since all plated lead terminal surfaces in the encapsulated semiconductor package of the disclosure are located at the tip or free end of the lead terminal, the solder will also be focusses at said tip. This has several beneficial effects. First, less solder could be used, since there is no waste solder flowing towards the encapsulant. Second, the structural sturdiness of the connection to the PCB is greater, because all intended solder is partaking in forming the connection. Third, unwanted electrical connections can be reduced, because the position of the solder is improved.

In a further example, the plating of the at least partially plated first side surface portion adjoins the top surface of the exposed lead end. Having the first side portion top being plated will encourage/attract the formation of the solder fillet, even the portion is not plated. If both top and bottom side were not plated, the solder will not easy form on the exposed lead end.

In yet another example, the at least one notch extends from the bottom lead surface towards the top lead surface.

In an alternative example, the at least one notch extends from the free lead end surface to the bottom lead surface or to the top lead surface.

The benefit of a notch extending from the bottom lead surface towards the top lead surface is that visual inspection of the solder connection can be performed. Furthermore, for a given depth of the notch seen from the free lead end surface, a greater surface area can be obtained with such kind of notch.

The benefit of a notch extending from the free lead end surface to the bottom lead surface is that mechanical rigidity perpendicular to the PCB may be provided depending on the shape of the notch.

Therefore, in an example of the encapsulated semiconductor package, the at least one notch is triangularly shaped, semi-circularly shaped, rectangularly shaped, star shaped, or cross shaped. Note, that or any suitable shape can be manufactured can be a feasible configuration for the various shapes.

These various shaped should be viewed from both the free end surface as well as from the bottom surface. In that regard, both viewpoints may reveal a different shape. E.g. a triangular shape could be seen from the free end surface, while a rectangular shape could be seen from the bottom surface. These views would then indicate a notch in the shape of a triangular prism.

In a further example, the at least one lead terminal comprises a taper.

The inventors have found that, providing a taper in the at least one lead terminal is beneficial for both the solder concentration at the tip of the lead terminal upon (reflow) soldering of the incapsulated semiconductor package to a PCB as well as aiding the mechanical connection of the lead terminal to the PCB.

In a preferable example, the taper is shaped such that the narrower end of the taper is close to the free lead end surface and that the wider end of the taper is close to the encapsulant.

In a more detailed preferred example, the taper is provided in the first side surface portion of both the first side surface and second side surface. This taper would then be visible when viewed from the top surface or bottom surface.

In a particular example, a taper angle is in the range between 5 to 50 degrees, preferably 15 to 30 degrees.

Herein should be understood that 0 degrees mean that there is no taper and 90 would mean the two surfaces are perpendicular to each other. The taper angle is to be understood as being the angle between the surfaces, when virtually placed together. This means that the taper angle of 90 degrees would mean the angle between the two surfaces. Therefore, in an example, an angle of 10 degrees means an angle of 5 degrees each compared to the reference line. In another example, the 10 degrees angle is divided unevenly. E.g. an angle of 2 degrees for one surface and an angle of 8 degrees for the other.

In another example of the encapsulated semiconductor package, the at least one notch forms at least less than 50% of the lead end surface, preferably less than 30%.

The inventors have found that at least 50%, preferably at least 70% of the free lead end surface should remain for adequate connection to the PCB. This example could thus be understood from the following exemplary case. E.g. a notch extending from the bottom to the top surface having a rectangular shape seen from the free lead end surface could have a width of 100 μm. When provided in the center of the free lead end surface both surface portions on both sides of the notch should that have a width of at least more than 50 μm (for each surface portion), preferably a width of at least more than 116⅔ μm. These values would mean that the notch forms at least less than 50% (being 100 μm of the total area of at least 200 μm) and preferably forms at least less than 30% (being 100 μm of the total area of at least 333⅓ μm).

In a further example, the plating has a thickness of at least 7 μm, preferably in the range of 7 μm to 15 μm.

In yet another example, the plating material is selected from a list of Tin (Sn), silver tin alloy (AgSn), Palladium (Pd) or a similar plating that will avoid or control lead oxidation.

The second aspect of the disclosure pertains to a method of manufacturing an encapsulated semiconductor package comprising the steps of:
providing an encapsulated semiconductor package comprising at least one lead terminal which is connected to a lead frame;
plating the lead frame and the lead terminal with plating material;
trimming the lead frame from the lead terminal, such that a fully plated free lead end surface is formed, which has not been subjected to trimming, wherein the fully plated free lead end surface comprises at least one fully plated notch.

The benefit of this method of manufacturing an encapsulated semiconductor package is that it can be guaranteed that the free lead end surface is fully plated, while comprising a fully plated notch as well. In prior art methods, the trimming of the lead terminal from the lead frame is performed such that the free lead end surface becomes unplated or partially plated, thereby minimizing its ability to make effective solder connections. The method of the disclosure utilized “sacrificial” cuts through the lead frame to create surfaces (first surface portion) in the proximity of the free lead end surface, such that can be guaranteed that the free lead end surface is pristine and plated. The cutting process of the lead frame to create these surfaces make it such that these first surface portions are/become partially plated. The inventors have found that manufacturing the encapsulated semiconductor packages this way is beneficial, since having a fully plated free lead end surface actually concentrates the solder at the tip of the lead terminal upon (reflow) soldering.

In an example of the method, the step of trimming is performed on a first side surface portion of both a first side surface and a second side surface of the at least one lead terminal, wherein the first side surface portion is proximate to the free lead end surface, wherein the first side surface portion of both the first side surface and the second side surface is at least partially plated with plating material.

It is beneficial to perform the trimming on the first side surface portion of both the first side surface and second side surface, since these surface portions are proximate to the free lead end surface, thereby a solder concentration at the free lead end surface will be created. Namely, the first side surface portions have less preferable surface chemistry, conditions, or surface energies for liquid solder to adhere onto, such that they act as barriers for solder to flow away.

In another example, the step of trimming is performed such that the first side surface portion of both the first side surface and the second side surface are angled at each other, thereby forming at least one taper in the lead terminal.

Such taper in the first side surface portion of both the first side surface and the second side surface ensures a more stability connection and may also facilitate the barrier effect of both side surfaces better.

In a further example of the method, the step of trimming is performed by a stamping, etching, cutting, laser cutting, water jetting, or plasma cutting process.

All in all, the encapsulated semiconductor package and method of manufacturing one provide an improved electrical and mechanical connection with a PBC by providing at least a fully plated free lead end surface of the lead terminal. Further, the mechanical connection with the PBC is improved by providing at least one fully plated notch in the free lead end surface of the at least one lead terminal, located either at the middle or corners of the terminals. The manufacturing thereof is achieved by providing “sacrificial” surfaces in the proximity of the free lead end surface, such that can be guaranteed that at least the free lead end surface is fully plated. These “sacrificial” surfaces will become at least partially plated due to the manufacturing process.

### BRIEF DESCRIPTION OF THE DRAWINGS

The disclosure will now be discussed with reference to the drawings, which show in:

FIG. 1 an encapsulated semiconductor package according to the disclosure.

FIG. 2 a zoom-in on an example of a lead terminal according to the disclosure.

FIG. 3 a zoom-in on another example of a lead terminal according to the disclosure.

FIG. 4 a zoom-in on yet another example of a lead terminal according to the disclosure.

FIG. 5 a zoom-in on a further example of a lead terminal according to the disclosure.

FIG. 6 shows a block diagram of the steps of a method of manufacturing an encapsulated semiconductor package.

FIG. 7 shows a semiconductor package 1000 prior to the trimming step.

### DETAILED DESCRIPTION

For a proper understanding of the disclosure, in the detailed description below corresponding elements or parts of the disclosure will be denoted with identical reference numerals in the drawings.

The following descriptions of the figures are intended to explain the working and essence of the claims. These figures are exemplary and are used to highlight particular features of claimed matter. The skilled person in the art would understand that these are not meant to limit the scope of protection, but that the scope is defined in the claims. The following features may thus be interchanged as the skilled person may seem fit.

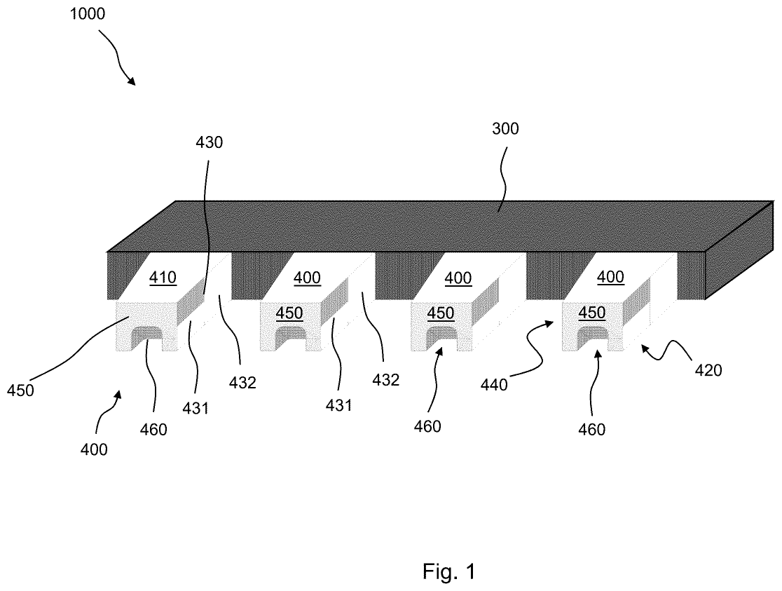

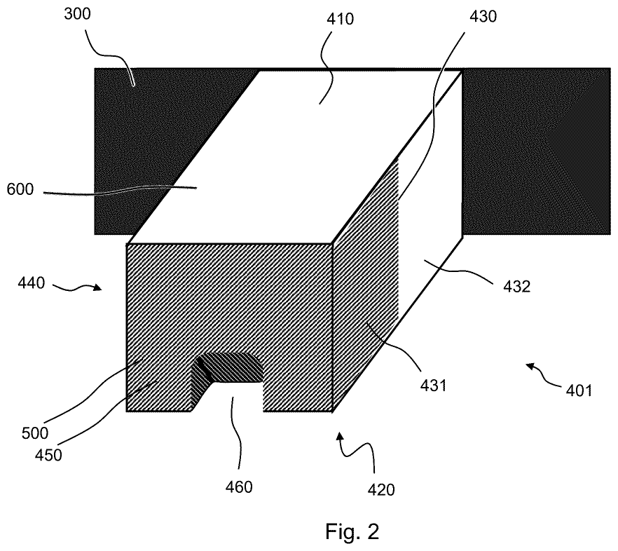

In FIG. 1 a three-dimensional view of an encapsulated semiconductor package 1000 according to the disclosure is shown. The semiconductor package 1000 comprises eight lead terminals extending out of the encapsulant 300. These lead terminals are adapted to both mechanically and electrically connect the encapsulated semiconductor package 1000 to further circuitry, like a PCB. A zoom-in of such lead terminal 400 is shown in FIG. 2. To ensure a better connection, each lead terminal 400 comprises a free lead end surface 450, being the surface furthest away from the encapsulant 300, which is fully plated with plating material 600. This plating material 600 may be Tin (Sn) or silver tin alloy (AgSn), or any similar plating that will reduce or avoid the oxidation of the metal terminals. Due to the chemical properties and the surface energies, it is such that upon (reflow) soldering, a larger volume of solder used for connecting the encapsulated semiconductor package 1000 concentratedly form at this free lead end surface 450. In order words, a larger amount of solder is concentrated at the tip of each lead terminal, thereby guaranteeing that the connection is strong and as intended. Furthermore, the top surface 410 and bottom surface 420 of each lead terminal 400 are plated 600, and the side surfaces 430/440 are partially plated, brought by the dam bar shearing/trimming/cutting process.

Furthermore, the encapsulated semiconductor package 1000 of FIG. 1 comprises a notch 460 in each lead terminal 400 extending from the free lead end surface 450 towards the bottom surface 420. The shape of this notch 460 is a rounded rectangle, however, any shape is possible, seen from the free lead end surface 450 and a true rectangle as seen from the bottom surface 420. Such a notch 460 ensures that liquified solder will flow into its volume, which after solidification creates an anchor for the encapsulated semiconductor package 1000 to adhere and latch onto. Additionally, the notch 460 creates a larger surface area on the free lead end surface 450, thereby absorbing a larger volume of solder, improving the solder connection as compared with prior art lead terminals.

It should be noted that the side surface 430/440 of each lead terminal 400 of the semiconductor package 1000 comprises a first side surface portion 431 and a second side surface portion 432, wherein the first side surface portion 431 is proximate to the free lead end surface 450 and the second side surface portion 432 is proximate to the encapsulant 300. Further, the first side surface portion 431 is at least partially plated while the side surface portion 432 is not plated.

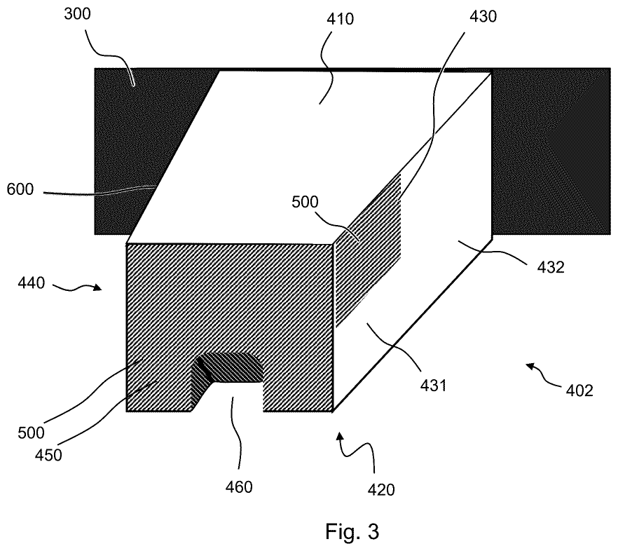

In FIG. 3 another example of a lead terminal 402 according to the disclosure is shown. This lead terminal 400 differs from the lead terminal 400 of FIG. 2 in that the first side surface portion 431 is partially plated, and the plating in the particular example of FIG. 3 is adjoining the top surface 410 of the lead terminal 400. Furthermore, the exemplary lead terminal 400 of FIG. 3 differs in the shape of the notch 460. Namely here, the notch 460 is shown to have a triangular shape as seen from the free lead end surface 450, while having a rectangular shape as seen from the bottom surface 420. However, any shape can be generated by a skilled person. The benefit of such a notch 460 may be that next to in-plane stability, stability perpendicular to the PCB can be guaranteed for the semiconductor package 1000. An inverted triangular shape as compared to the notch 460 of FIG. 3 would create two latches for a Z-dependent latching effect.

Furthermore, the lead terminal 402 is shown to comprise a taper, such that vertices at the encapsulant 300 of the top surface 410, bottom surface 420, first side surface 430, and second side surface 430 are larger than the vertices of those surfaces at the free lead end surface 450. Such a taper increases the sturdiness of a lead terminal 402 and helps towards focusing the liquified solder at the tip end of said lead terminal 402.

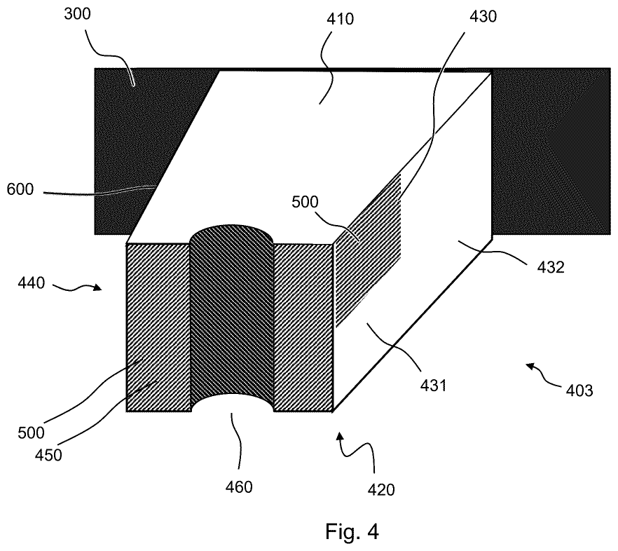

Next in FIG. 4 another exemplary zoom-in of a lead terminal 403 of a semiconductor package 1000 according to the disclosure is shown, which compared to the previous two figures comprises a notch 460 which extends from the top surface 410 to the bottom surface 420. The benefit of a notch 460 as seen in FIG. 4 is that visual inspection of the solder after soldering can be performed from the top surface 410. Furthermore, the effective plated surface area of the lead terminal 400 is larger in FIG. 4 than shown be in FIG. 3, thereby allowing for a better connection of the solder to the lead terminal 403. Furthermore, the partial plating on the first side surface portion 431 adheres the top surface 410 similarly as the lead terminal 402 of FIG. 3.

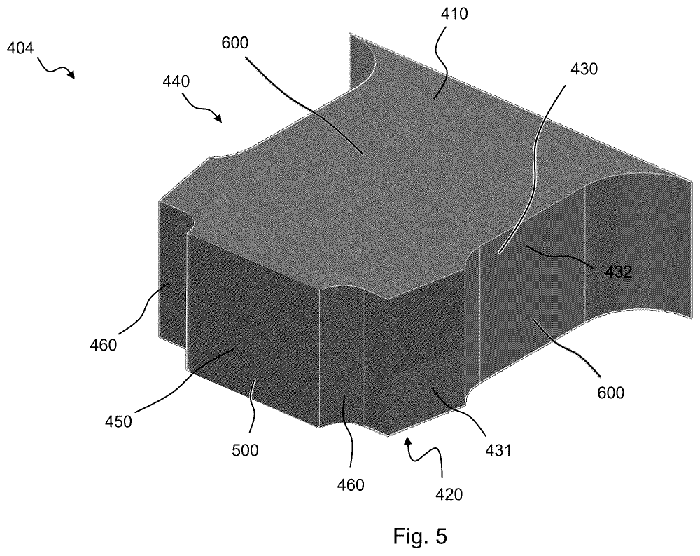

In FIG. 5 yet another three-dimensional zoom-in of a lead terminal 404 of a semiconductor package 1000 according to the disclosure is shown. This exemplary lead terminal 400 has a more complicated shape, because of the present of multiple different surfaces and roundings. Yet, the same constitutive features as in the previous lead terminals 400 are present. A free lead end surface 450 is shown, this time, comprising two notches provided at the edges of the free lead end surface 450. Said free lead end surface 450 is also ensured to be fully plated with plating material 600. Further, the lead terminal 400 of FIG. 5 comprises two parallel second side surface portions 432/442, and tapered first side surface portions 431 of the side surfaces 430/440. These first side surface portions 431 are at least partially plated with plating material 600, while side surface portion 432 is not plated, as an impact of plastic generated during molding process. That way, the same functionality and benefits are guaranteed for the lead terminal 404 of FIG. 5 as for the lead terminals 400 of the other figures.

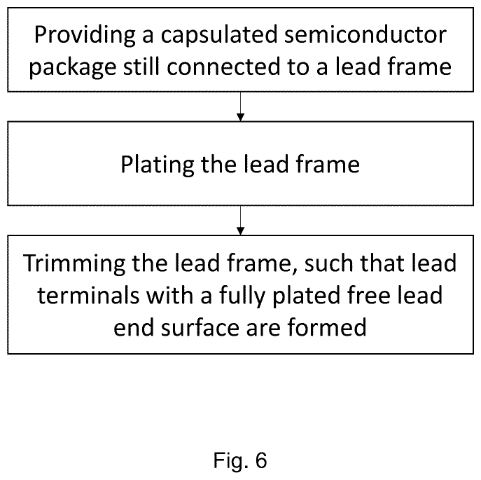

Lastly, in FIG. 6, the steps of a method of manufacturing an encapsulated semiconductor package 1000 according to the disclosure are shown in a block diagram. The method comprises the steps of:
providing a capsulated semiconductor package 1000 comprising at least one lead terminal 400 which is still connected to a lead frame;
plating the lead frame and the lead terminal 400 with plating material 600;
trimming the lead frame from the lead terminal 400, such that a fully plated free lead end surface 450 is formed, which has not been subjected to trimming, wherein fully plated free lead end surface 450 comprises at least one fully plated notch 460.

Preferably the trimming is performed on a first side surface portion 431 of both a first side surface 430 and a second side surface 440 of the at least one lead terminal 400, wherein the first side surface portion 431 is proximate to the free lead end surface 450, wherein the first side surface portion 431 of both the first side surface 430 and the second side surface 440 is at least partially plated with plating material 600.

That way it can be assured that the free lead end surface 450 remains pristine and fully plated. The first side surface portions 431 are then initially connected to the initial lead frame before trimming and are “sacrificial” surfaces, meaning they become partially plated due to the trimming process. It can thus not be assured that the first side surface portions 431/441 are fully plated 600 or that they are fully unplated.

The obtained semiconductor package 1000 has an improved connection to further circuitry due to a fully plated free lead end surface 450 comprising a fully plated notch 460 as explained throughout various sections of this disclosure.

The step of trimming is performed such that the first side surface portion 431 of both the first side surface 430 and the second side surface 440 are angled at each other, thereby forming at least one taper in the lead terminal 400.

The trimming is performed by a stamping, etching, cutting, laser cutting, water jetting, or plasma cutting process. These processes typically cut from the top surface 410 towards the bottom, thereby displacing some residual plating material 600 onto the first side surface portion 431/441, such that said surface portion 431/441 becomes partially plated.

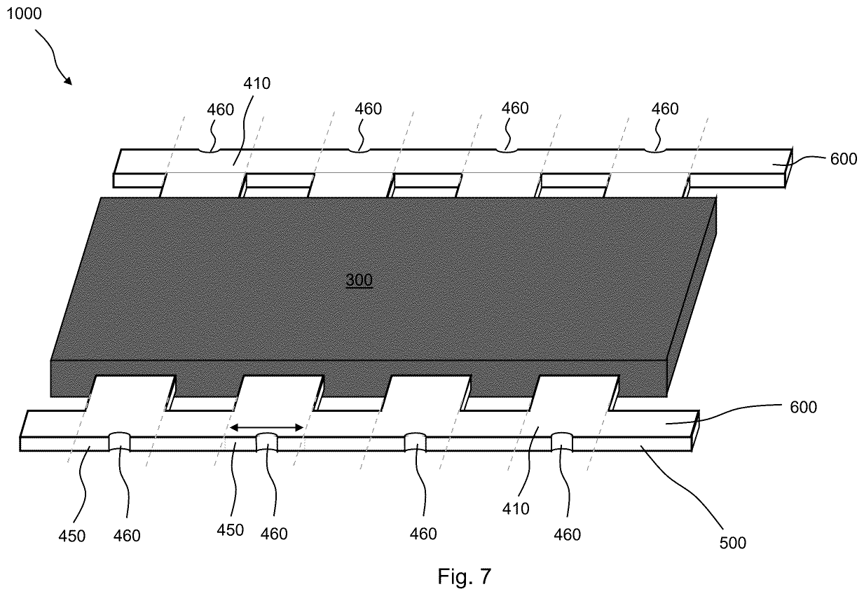

In FIG. 7 a semiconductor package 1000 prior to the trimming step is shown, wherein dashed lines are indicated along which the trimming occurs. Here the intended steps and the subsequent result of the method according to the disclosure are depicted clearly, since it can be seen that the free lead end surface 450 is unaffected by the trimming action.

All in all, the encapsulated semiconductor packages 1000 and the method of manufacturing one provide an improved electrical and mechanical connection with further circuitry by providing at least a fully plated free lead end surface 450 of the lead terminal 400. Further, the mechanical connection with the further circuitry is improved by providing at least one fully plated notch 460 in the free lead end surface 450 of the at least one lead terminal 400.

### REFERENCE NUMBERS

1000 semiconductor package
100 substrate
200 semiconductor die
300 encapsulant
400 lead terminal
401-402-etc. first, second, etc. lead terminal according to the disclosure
410 top surface
420 bottom surface
430 first side surface
431 first side surface portion
432 second side surface portion
440 second side surface
441 first side surface portion
442 second side surface portion
450 free lead end surface
460 notch
500 plating material
600 lead terminal material

1. An encapsulated semiconductor package comprising:
at least one lead terminal having an exposed lead end extending from the encapsulated semiconductor package, wherein the exposed lead end comprises a free lead end surface, wherein the free lead end surface comprises at least one notch; and
wherein the free lead end surface and the at least one notch are plated with a plating material.

2. The encapsulated semiconductor package according to claim 1, wherein the exposed lead end comprises a top lead surface and a bottom lead surface opposite to the top lead surface, both the top surface and the bottom surface extend from the encapsulated semiconductor package towards the free lead end surface; and
a first side surface and a second side surface opposite to the first side surface, both extending from the encapsulated semiconductor package to the lead end surface, wherein the first side surface and the second side surface both extend from the top lead surface to the bottom lead surface,
wherein each of the first side surface and the second side surface comprise a first side surface portion and a second side surface portion, the first side portion being in proximity of the free lead end surface and the second side portion being in proximity of the encapsulated semiconductor package, and wherein the first side surface portion is at least partially plated with plating material.

3. The encapsulated semiconductor package according to claim 2, wherein the at least partially plating of the first side surface adjoins the top surface of the exposed lead end.

4. The encapsulated semiconductor package according to claim 2, wherein the at least one notch extends from the bottom lead surface towards the top lead surface.

5. The encapsulated semiconductor package according to claim 2, wherein the at least one notch extends from the free lead end surface to the bottom lead surface or to the top lead surface.

6. The encapsulated semiconductor package according to claim 1, wherein the at least one notch is selected from a shape consisting of: triangularly shaped, semi-circularly shaped, rectangularly shaped, star shaped, and cross shaped.

7. The encapsulated semiconductor package according to claim 1, wherein the at least one lead terminal comprises a taper.

8. The encapsulated semiconductor package according to claim 7, wherein the taper has an angle that is in the range between 5 to 50 degrees.

9. The encapsulated semiconductor package according to claim 1, wherein the at least one notch forms at least less than 50% of the lead end surface.

10. The encapsulated semiconductor package according to claim 1, wherein the plating has a thickness of at least 7 μm.

11. The encapsulated semiconductor package according to claim 1, wherein the plating material is selected from of the group consisting of: Tin (Sn), silver tin alloy (AgSn), and Palladium (Pd).

12. The encapsulated semiconductor package according to claim 2, wherein the plating has a thickness of at least 7 μm.

13. The encapsulated semiconductor package according to claim 2, wherein the plating material is selected from of the group consisting of: Tin (Sn), silver tin alloy (AgSn), and Palladium (Pd).

14. A method of manufacturing an encapsulated semiconductor package comprising the steps of:
providing a capsulated semiconductor package comprising at least one lead terminal that is still connected to a lead frame;
plating the lead frame and the lead terminal with plating material; and
trimming the lead frame from the lead terminal, so that a fully plated free lead end surface is formed, that has not been subjected to trimming, wherein the fully plated free lead end surface comprises at least one fully plated notch.

15. The method according to claim 14, wherein the step of trimming is performed on a first side surface portion of both a first side surface and a second side surface of the at least one lead terminal, wherein the first side surface portion is proximate to the free lead end surface, and wherein the first side surface portion of both the first side surface and the second side surface is at least partially plated with plating material.

16. The method according to claim 15, wherein the step of trimming is performed such that the first side surface portion of both the first side surface and the second side surface are angled at each other, thereby forming at least one taper in the lead terminal.

17. The method according to claim 14, wherein the trimming is performed by a process selected from the group consisting of: stamping, etching, cutting, laser cutting, water jetting, and plasma cutting.

18. The method according to claim 15, wherein the trimming is performed by a process selected from the group consisting of: stamping, etching, cutting, laser cutting, water jetting, and plasma cutting.
